(19) United States
(12) Patent Application Publication
(10) Pub. No.: US 2025/0321256 A1
(43) Pub. Date: Oct. 16, 2025

(54) POWER CONVERSION DEVICE AND PROGRAM

(71) Applicant: DENSO CORPORATION, Kariya-city (JP)

(72) Inventors: Naoto KOBAYASHI, Nisshin-city (JP); Yuichi HANDA, Kariya-city (JP); Yuuki TSUTSU, Kariya-city (JP)

(73) Assignee: DENSO CORPORATION, Kariya-city (JP)

(21) Appl. No.: 19/249,042

(22) Filed: Jun. 25, 2025

Related U.S. Application Data
(63) Continuation of application No. PCT/JP2023/033162, filed on Sep. 12, 2023.

(30) Foreign Application Priority Data
Dec. 26, 2022 (JP) 2022-209023

(51) Int. Cl. G01R 27/26; H02M 3/00; H02M 3/335

(52) U.S. Cl. CPC G01R 27/2611; H02M 3/01; H02M 3/33573; H02M 3/33576

(57) ABSTRACT

A power conversion device includes a first circuit connected to a first external terminal, a second circuit connected to a second external terminal, an inductance element connecting a first AC terminal of the first circuit and a second AC terminal of the second circuit, a resonant capacitor connected to the inductance element, and a control unit. The control unit performs a power transfer process to transfer power between the first external terminal and the second external terminal via the inductance element by switching control of at least one of the first circuit and the second circuit, and an estimation process to estimate the inductance by outputting a test voltage to the inductance element. A frequency of the fundamental wave component of the test voltage is set to a frequency lower than a frequency of the fundamental wave component of a voltage output to the inductance element in the power transfer process.

### CROSS-REFERENCE TO RELATED APPLICATION

This application is the U.S. bypass application of International Application No. PCT/JP2023/033162 filed on Sep. 12, 2023 which designated the U.S. and claims priority to Japanese Patent Application No. 2022-209023 filed on Dec. 26, 2022, the contents of both of which are incorporated herein by reference.

### TECHNICAL FIELD

The present disclosure relates to a power conversion device and program.

### BACKGROUND

Conventional power conversion devices are known to include a first circuit, which is a bridge circuit connected to a first external terminal, a second circuit, which is a bridge circuit connected to a second external terminal, and a transformer connecting a first AC terminal of the first circuit and a second AC terminal of the second circuit. As an embodiment of this power conversion device, JP 2017-85704 A, for example, discloses a multi-port converter. The power conversion device disposed in JP 2017-85704 A is capable of estimation of transformer inductance.

### SUMMARY

The present disclosure includes a first circuit, which is a bridge circuit connected to a first external terminal,
a second circuit, which is a bridge circuit connected to a second external terminal,
an inductance element connecting a first AC terminal of the first circuit and a second AC terminal of the second circuit,
a resonant capacitor connected to the inductance element, and
a control unit, wherein
the control unit performs:
a power transfer process to transfer power between the first external terminal and the second external terminal via the inductance element by switching control of at least one of the first circuit and the second circuit, and
an estimation process to estimate an inductance of the inductance element by outputting a test voltage to the inductance element, wherein
a frequency of a fundamental wave component of the test voltage is set to a frequency lower than a frequency of a fundamental wave component of a voltage output to the inductance element in the power transfer process.

### BRIEF DESCRIPTION OF THE DRAWINGS

The above features of the present disclosure will be made clearer by the following detailed description, given referring to the appended drawings. In the accompanying drawings:

FIG. 1 shows an overall configuration of a power conversion device according to a first embodiment;

FIG. 2 shows a diagram of a circuit state in a process of estimating an excitation inductance of a first transformer;

FIG. 3 shows timing charts of test voltages;

FIG. 4 shows a diagram of a circuit state in a process of estimating ab excitation inductance of a second transformer;

FIG. 5 shows a diagram of impedance-frequency characteristics of a resonant capacitor and an excitation inductance;

FIG. 6 shows a diagram of impedance-frequency characteristics of first and second closed-loop circuits;

FIG. 7 shows a flowchart of a procedure for estimating the excitation inductance;

FIG. 8 shows a diagram of a calculated effect of improved estimation accuracy;

FIG. 9 shows an overall configuration of aa power conversion device according to a second embodiment;

FIG. 10 shows a flowchart of a procedure for estimating the excitation inductance;

FIG. 11 shows an overall configuration of a power conversion device according to a third embodiment;

FIG. 12 shows a diagram of an output mode of a test voltage according to the fourth embodiment;

FIG. 13 shows timing charts of test voltages;

FIG. 14 shows a diagram of an example of current sampling timing;

FIG. 15 shows a diagram of another example of current sampling timing;

FIG. 16 shows an overall configuration of a power conversion device according to a fifth embodiment;

FIG. 17 shows an overall configuration of a power conversion device for a variation of the fifth embodiment;

FIG. 18 shows an overall configuration of another power conversion device for a variation of the fifth embodiment;

FIG. 19 shows an overall configuration of a power conversion device for according to another embodiment;

FIG. 20 shows an overall configuration of another power conversion device according to the other embodiment;

FIG. 21 shows an overall configuration of yet another power conversion device for other embodiment; and

FIG. 22 shows an overall configuration of a power conversion device according to the other embodiment.

### DETAILED DESCRIPTION OF THE PREFERRED EMBODIMENTS

In addition to the devices disclosed in JP 2017-85704 A, there are other power conversion devices that can use LC resonance to reduce switching losses. In detail, a power conversion device includes an inductance element connecting a first AC terminal of a first circuit and a second AC terminal of a second circuit, and a capacitor connected to the inductance element. In this power conversion device, a test voltage is output to the inductance element when estimating the inductance of the inductance element. If the frequency of the test voltage is not set properly, the accuracy of the inductance estimation of the inductance element can be reduced.

The main purpose of the present disclosure is to provide a power conversion device and program that can suppress an estimation accuracy of an inductance from being reduced.

The present disclosure includes a first circuit, which is a bridge circuit connected to a first external terminal,
a second circuit, which is a bridge circuit connected to a second external terminal,
an inductance element connecting a first AC terminal of the first circuit and a second AC terminal of the second circuit,
a resonant capacitor connected to the inductance element, and
a control unit, wherein
the control unit performs:
a power transfer process to transfer power between the first external terminal and the second external terminal via the inductance element by switching control of at least one of the first circuit and the second circuit, and
an estimation process to estimate an inductance of the inductance element by outputting a test voltage to the inductance element, wherein
a frequency of a fundamental wave component of the test voltage is set to a frequency lower than a frequency of a fundamental wave component of a voltage output to the inductance element in the power transfer process.
   The impedance of the resonant capacitors tends to be larger at lower frequencies. On the other hand, the impedance of the inductance element tends to be smaller at lower frequencies.

Therefore, setting the frequency of the fundamental wave component of the test voltage output to the inductance element to a low frequency such that the current does not flow through the resonant capacitor as much as possible is considered to suppress the estimation accuracy of the inductance of the inductance element from being reduced.

In this regard, in the present disclosure, the frequency of the fundamental wave component of the test voltage is set to a frequency lower than the frequency of the fundamental wave component of the voltage output to the inductance element in the power transfer process. This allows the estimation process to output a test voltage with a low frequency that does not cause current to flow through the resonant capacitor as much as possible. As a result, it is possible to suppress the estimation accuracy of the inductance of the inductance element from being reduced.

A plurality of embodiments will be described with reference to the drawings. In the plurality of embodiments, functionally and/or structurally corresponding and/or associated parts may have the same reference numerals, or reference numerals with different digits above 100. For corresponding and/or associated parts, reference may be made to the description of other embodiments.

### First Embodiment

The first embodiment embodying a power conversion device of the present disclosure will be described below with reference to the drawings. The power conversion device of the present embodiment is of a multi-port type. Power conversion devices are mounted on moving bodies such as vehicles, aircrafts, or ships, for example. The vehicle may be, for example, a hybrid vehicle, an electric vehicle or a railroad vehicle.

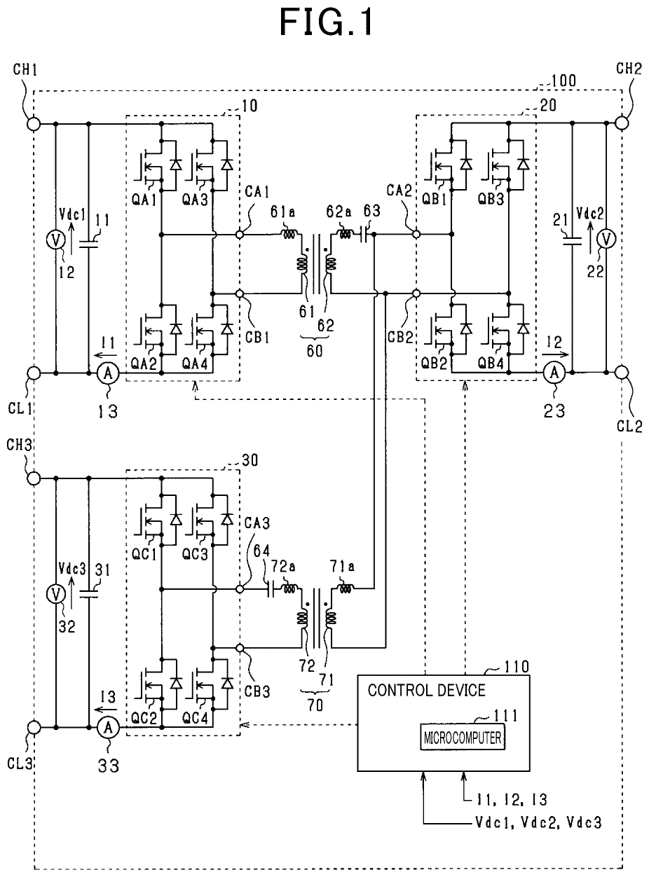

As shown in FIG. 1, a power conversion device 100 includes a plurality of external terminals and full-bridge circuits corresponding to each external terminal. Power is transferred between at least two of the external terminals by switching control of the full-bridge circuit.

The power conversion device 100 includes a first external terminal, a second external terminal, and a third external terminal. The first, second and third external terminals are connected to chargeable and dischargeable storage batteries, AC-DC converters, and electrical loads. A system is composed of chargeable and dischargeable storage batteries, AC-DC converters and electric loads, etc., and the power conversion device 100. The power conversion device 100 has a first full-bridge circuit 10 as a full-bridge circuit corresponding to a first high potential side terminal CH1 and a first low potential side terminal CL1, which are the first external terminals.

The first full-bridge circuit 10 includes first-A to fourth-A switches QA1 to QA4. In the present embodiment, the first-A to fourth-A switches QA1 to QA4 are N-channel MOSFETs and have body diodes. The first high potential side terminal CH1 is connected to drains, which are high potential side terminals of the first switch QA1 and the third-A switch QA3. A source, which is a low potential side terminal of the first-A switch QA1, is connected to a drain of the second-A switch QA2, and a source of the third-A switch QA3 is connected to a drain of the fourth-A switch QA4. The first low potential side terminal CL1 is connected to the sources of the second-A switch QA2 and the fourth-A switch QA4. A first end of a first capacitor 11 provided by the power conversion device 100 is connected to the first high potential side terminal CH1. A second end of the first capacitor 11 is connected to the first low potential side terminal CL1. The first capacitor 11 serves as a smoothing capacitor and noise rejection. Note that the first capacitor 11 may be built into the first full-bridge circuit 10.

The power conversion device 100 includes a second full-bridge circuit 20 as a full-bridge circuit corresponding to a second high potential side terminal CH2 and a second low potential side terminal CL2, which are the second external terminals. The second full-bridge circuit 20 includes first-B to fourth-B switches QB1 to QB4. In the present embodiment, the first-B to fourth-B switches QB1 to QB4 are N-channel MOSFETs and have body diodes. In the present embodiment, since the configuration of the second full-bridge circuit 20 is similar to that of the first full-bridge circuit 10, a detailed description of the second full-bridge circuit 20 is omitted.

A first end of a second capacitor 21 provided by the power conversion device 100 is connected to the second high potential side terminal CH2. A second end of the second capacitor 21 is connected to the second low potential side terminal CL2. The second capacitor 21 serves as a smoothing capacitor and noise rejection. Note that the second capacitor 21 may be built into the second full-bridge circuit 20.

The power conversion device 100 includes a third full-bridge circuit 30 as a full-bridge circuit corresponding to a third high potential side terminal CH3 and a third low potential side terminal CL3, which are third external terminals. The third full-bridge circuit 30 includes first-C to fourth-C switches QC1 to QC4. In the present embodiment, the first-C to fourth-C switches QC1 to QC4 are N-channel MOSFETs and have body diodes. In the present embodiment, since the configuration of the third full-bridge circuit 30 is similar to that of the first full-bridge circuit 10, a detailed description of the third full-bridge circuit 30 is omitted.

A first end of a third capacitor 31 provided by the power conversion device 100 is connected to the third high potential side terminal CH3. A second end of the third capacitor 31 is connected to the third low potential side terminal CL3. The third capacitor 31 serves as a smoothing capacitor and noise rejection. Note that the third capacitor 31 may be built into the third full-bridge circuit 30.

The power conversion device 100 includes a first transformer 60 (corresponding to a first inductance element) for transferring power between the first full-bridge circuit 10 and the second full-bridge circuit 20. The first transformer 60 includes a first coil 61, a second coil 62, and a core around which the first coil 61 and the second coil 62 are wound. The first coil 61 and the second coil 62 are magnetically coupled through the core.

A first end of the first coil 61 is connected to a first-A AC terminal CA1 of the first full-bridge circuit 10. A source of a first-A switch QA1 and a drain of a second-A switch QA2 are connected to the first-A AC terminal CA1. A second end of the first coil 61 is connected to a first-B AC terminal CB1 of the first full-bridge circuit 10. A source of a third-A switch QA3 and a drain of a fourth-A switch QA4 are connected to the first-B AC terminal CB1.

A first end of the second coil 62 is connected to a first end of a first resonant capacitor 63 provided by the power conversion device 100. A second end of the first resonant capacitor 63 is connected to a second-A AC terminal CA2 of the second full-bridge circuit 20. A second end of the second coil 62 is connected to a second-B AC terminal CB2 of the second full-bridge circuit 20. FIG. 1 also shows leakage inductances 61a and 62a of the first and second coils 61 and 62 together.

If the potential of the first end relative to the second end is higher in the first coil 61, an induced voltage is generated in the second coil 62 such that the potential of the first end is higher than the second end thereof. On the other hand, if the potential of the second end relative to the first end is higher in the first coil 61, an induced voltage is generated in the second coil 62 such that the potential of the second end is higher than the first end thereof.

The power conversion device 100 has a second transformer 70 (corresponding to a second inductance element) for transferring power between the second full-bridge circuit 20 and the third full-bridge circuit 30. The second transformer 70 includes a first coil 71 (corresponding to a third coil), a second coil 72 (corresponding to a fourth coil), and a core around which the first coil 71 and second coil 72 are wound. The first coil 71 and the second coil 72 are magnetically coupled through the core.

A first end of the first coil 71 is connected to a second-A AC terminal CA2. A second end of the first coil 71 is connected to a second-B AC terminal CB2. In other words, the first coil 71 of the second transformer 70 is connected in parallel to the series connection of the second coil 62 and the first resonant capacitor 63 of the first transformer 60.

A first end of the second coil 72 of the second transformer 70 is connected to a first end of a second resonant capacitor 64 provided by the power conversion device 100. A second end of the second resonant capacitor 64 is connected to a third-A AC terminal CA3 of the third full-bridge circuit 30. A second end of the second coil 72 is connected to a third-B AC terminal CB3 of the third full-bridge circuit 30. FIG. 1 also shows leakage inductances 71a, 72a of the first and second coils 71, 72 together.

If the potential of the first end relative to the second end is higher in the first coil 71, an induced voltage is generated in the second coil 72 such that the potential of the first end is higher than the second end thereof. On the other hand, if the potential of the second end relative to the first end is higher in the first coil 71, an induced voltage is generated in the second coil 72 such that the potential of the second end is higher than the first end thereof.

The power conversion device 100 includes a first voltage sensor 12, a second voltage sensor 22, and a third voltage sensor 32. The first voltage sensor 12 detects the voltage of the first capacitor 11, the second voltage sensor 22 detects the voltage of the second capacitor 21, and the third voltage sensor 32 detects the voltage of the third capacitor 31.

The power conversion device 100 includes a first current sensor 13, a second current sensor 23, and a third current sensor 33. The first current sensor 13 detects the current flowing between the first full-bridge circuit 10 and the first low potential side terminal CL1. The second current sensor 23 detects the current flowing between the second full-bridge circuit 20 and the second low potential side terminal CL2. The third current sensor 33 detects the current flowing between the third full-bridge circuit 30 and the third low potential side terminal CL3.

It should be noted that taking the first current sensor 13 as an example, the first current sensor 13 may, for example, detect the current flowing between the first full-bridge circuit 10 and the first high potential side terminal CH1.

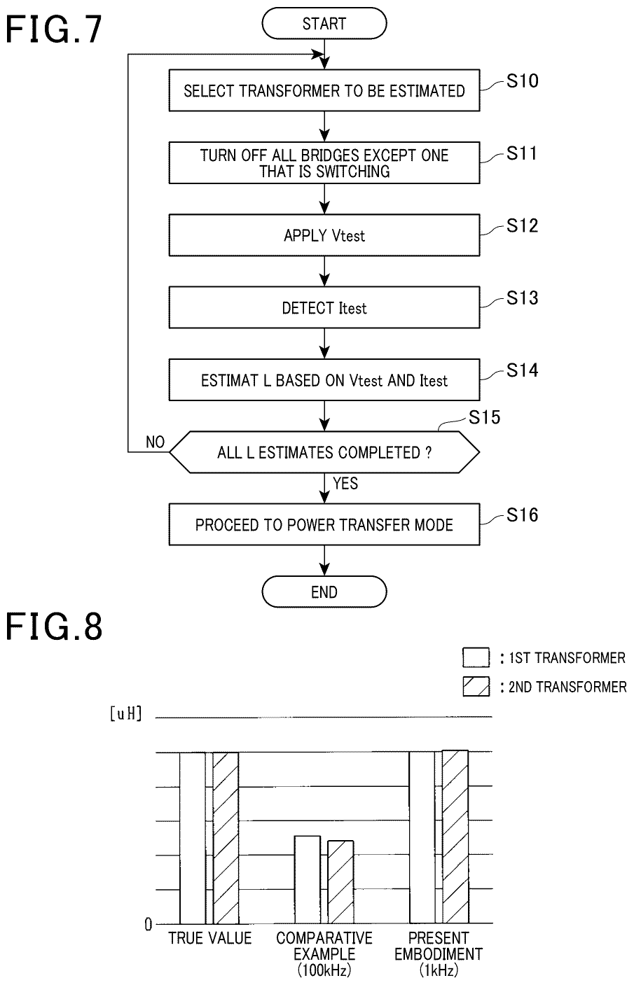

Detected values Vdc1, Vdc2, Vdc3 of the first, second and third voltage sensors 12, 22, 33 and detected values I1, I2, I3 of the first, second and third current sensors 13, 23, 33 are input to a control device 110 as a control unit provided by the power conversion device 100. The control device 110 is mainly composed of a microcomputer 111, and the microcomputer 111 is equipped with a CPU. The functions provided by the microcomputer 111 can be provided by software recorded in a substantive memory device and a computer executing it, software alone, hardware alone, or a combination thereof. For example, if the microcomputer 111 is provided by an electronic circuit that is hardware, it can be provided by a digital or analog circuit that contains many logic circuits. For example, the microcomputer 111 executes a program stored in a non-transitory tangible storage medium as its own storage unit. The program includes, for example, the program for the process shown in FIG. 7, etc., which will be described later. A program installed in the control device 110 is executed, whereby a method corresponding to the program is performed. The storage unit is, for example, a non-volatile memory. The program stored in the storage unit can be downloaded and updated via a communication network such as the internet, for example, OTA (over the air).

Next, a power transfer process performed by the control device 110 will be described.

The power transfer process is a process of transferring power between at least two of the first to third external terminals. This process utilizes an LC series resonant circuit consisting of a resonant capacitor and a leakage inductance.

A closed loop circuit including the first full-bridge circuit 10, the first transformer 60, the first resonant capacitor 63 and the second full-bridge circuit 20 is referred to as a first closed loop circuit. In the first closed loop circuit, the LC series resonant circuit is formed from the first resonant capacitor 63 and the leakage inductances 61a and 62a of the first transformer 60. In the present embodiment, the values of the leakage inductances 61a and 62a are equal.

A closed loop circuit including the second full-bridge circuit 20, the second transformer 70, the second resonant capacitor 64 and the third full-bridge circuit 30 is referred to as a second closed loop circuit. In the second closed loop circuit, the LC series resonant circuit is formed from the second resonant capacitor 64 and the leakage inductances 71a, 72a of the second transformer 70. In the present embodiment, the values of the leakage inductances 71a and 72a are equal. In addition, in the present embodiment, the values of the leakage inductances 61a, 62a, 71a, 72a of each transformer 60, 70 are equal.

Note that in the first and second closed loop circuits, an additional inductor, which is a passive element component, may be provided in place of the leakage inductance as the inductance that constitutes the LC series resonant circuit.

A case where power is transferred between the first external terminal and the second external terminal will be described. A control method of power transfer can be adopted, for example, the method described in JP 2021-145407 A.

The control device 110 alternately turns on the pair of the first-A switch QA1 and the fourth-A switch QA4 and the pair of the second-A switch QA2 and the third-A switch QA3. In addition, the control device 110 alternately turns on the pair of the first-B switch QB1 and the fourth-B switch QB4 and the pair of the second-B switch QB2 and the third-B switch QB3. The control device 110 can control the direction and amount of power transfer by adjusting the phase difference between the switching timing of the first-A switch QA1 to off and the switching timing of the first-B switch QB1 to off.

Next, a case where power is transferred between the second external terminal and the third external terminal will be described. The control device 110 alternately turns on the pair of the first-B switch QB1 and the fourth-B switch QB4 and the pair of the second-B switch QB2 and the third-B switch QB3. In addition, the control device 110 alternately turns on the pair of the first-C switch QC1 and the fourth-C switch QC4 and the pair of the second-C switch QC2 and the third-C switch QC3. The control device 110 can control the direction and amount of power transfer by adjusting the phase difference between the switching timing of the first-B switch QB1 to off and the switching timing of the first-C switch QC1 to off.

A switching frequency fβ of each switch QA1 to QA4, QB1 to QB4, and QC1 to QC4 in the power transfer process is set to a frequency on the higher side of the higher of the resonant frequencies of the first and second closed loop circuits (for example, 100 kHz). For example, if the capacitance of the first resonant capacitor 63 and the capacitance of the second resonant capacitor 64 are equal, the resonant frequencies of the first and second closed loop circuits will have equal values. In the present embodiment, a switching period Tβ (=1/fβ) of each switch QA1 to QA4, QB1 to QB4, and QC1 to QC4 is set equal. The closer the switching frequency fβ is to the resonant frequency, the greater the reduction in switching losses of the switch. Note that the switching frequency fβ should be set above 1.3 times the resonance frequency and below twice the resonance frequency, for example.

Next, a process of estimating an excitation inductance of a transformer executed by the control device 110 will be described.

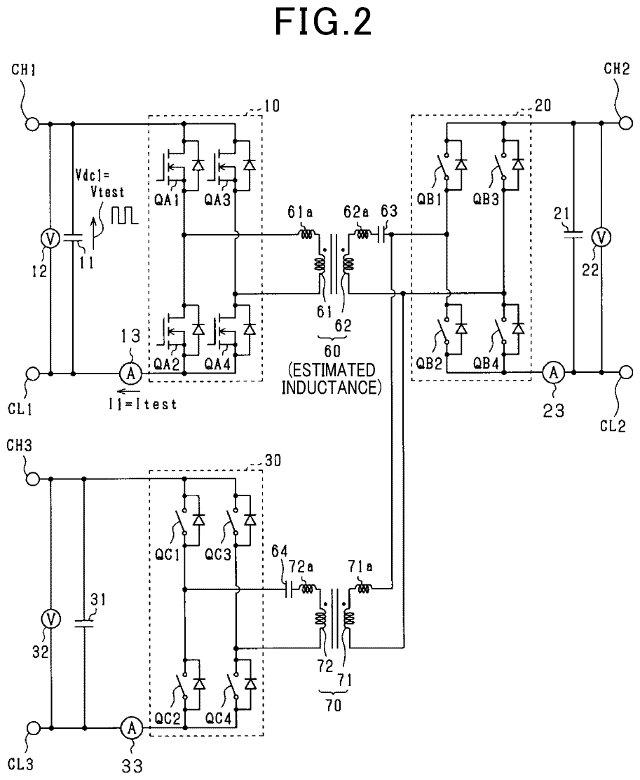

First, a method of estimating an excitation inductance of the first transformer 60 is described using FIG. 2. In FIG. 2, each AC terminal and other terminals are omitted.

The excitation inductance of the first transformer 60 is an inductance related to the magnetic flux (excitation flux) that chains both the first and second coils 61, 62 of the magnetic flux generated by energizing one of the first and second coils 61, 62.

The control device 110 turns off all the switches provided by each of the full-bridge circuits 10, 20, and 30 except the full-bridge circuit that is the output source of a test voltage Vtest. In detail, the control device 110 turns off all switches QB1 to QB4 in the second full-bridge circuit 20 and all switches QC1 to QC4 in the third full-bridge circuit 30.

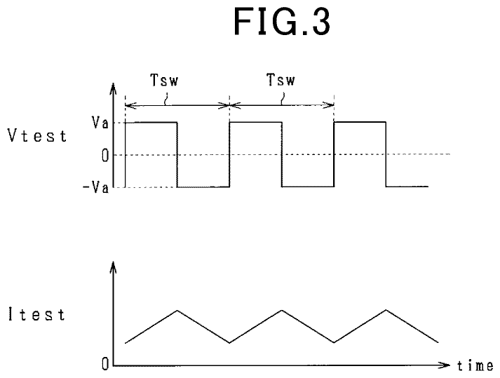

The control device 110 has a function of setting the frequency of the test voltage Vtest. The frequency of the test voltage Vtest is set so that the fundamental wave component of the test voltage Vtest is the frequency described below. The control device 110 alternately turns on the pair of first-A switch QA1 and fourth-A switch QA4 and the pair of second-A switch QA2 and third-A switch QA3 when each switch QB1 to QB4 and QC1 to QC4 are off. This causes the test voltage Vtest to be output from the first full-bridge circuit 10 to the first coil 61 of the first transformer 60. The test voltage Vtest is an AC voltage with amplitude Va, specifically a square wave voltage, as shown in FIG. 3. Va is a voltage equivalent to a terminal voltage of the first capacitor 11. In the present embodiment, the control device 110 detects a detected value Vdc1 of the first voltage sensor 12 as the test voltage Vtest and uses the detected test voltage Vtest to estimate the excitation inductance. In FIG. 3, Tsw indicates the switching period of each switch QA1 to QA4 of the first full-bridge circuit 10 in the estimation process.

When the test voltage Vtest is applied to the first coil 61, a current flows through the first coil 61. The current flowing in the first coil 61 is detected by the first current sensor 13. The control device 110 estimates an excitation inductance L1 of the first transformer 60 based on the test voltage Vtest detected by the first voltage sensor 12 and the current Itest (corresponding to a first current for estimation) detected by the first current sensor 13. In detail, the control device 110 estimates the excitation inductance L1 of the first transformer 60 by dividing the amplitude Va of the detected test voltage Vtest by the rate of change of the detected current Itest (e.g., rate of rise or fall).

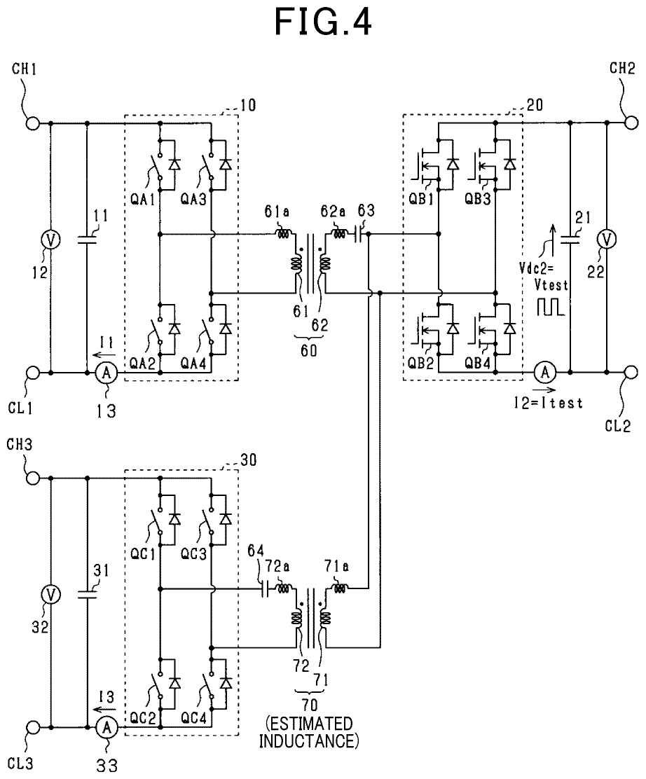

Next, a method of estimating an excitation inductance of the second transformer 70 is described using FIG. 4.

The control device 110 turns off all switches QA1 to QA4 in the first full-bridge circuit 10 and all switches QC1 to QC4 in the third full-bridge circuit 30. The control device 110 alternately turns on the pairs of the switches 1B QB1 and 4B QB4 and the pairs of the switches 2B QB2 and 3B QAB when each switch QA1 to QA4 and QC1 to QC4 are turned off. This causes the test voltage Vtest shown in FIG. 3 to be output from the second full-bridge circuit 20 to the first coil 71 of the second transformer 70.

When the test voltage Vtest is applied to the first coil 71, a current flows through the first coil 71. The current flowing in the first coil 71 is detected by the second current sensor 23. In the process of estimating the excitation inductance of the second transformer 70, the control device 110 detects a detected value Vdc2 of the second voltage sensor 22 as the test voltage Vtest and uses the detected test voltage Vtest for estimating the excitation inductance. The control device 110 estimates an excitation inductance L2 of the second transformer 70 based on the test voltage Vtest detected by the second voltage sensor 22 and the current Itest (corresponding to a second current for estimation) detected by the second current sensor 23. In detail, the control device 110 estimates the excitation inductance L2 of the second transformer 70 by dividing the amplitude Va of the detected test voltage Vtest by the rate of change of the detected current Itest (e.g., rate of rise or fall).

Note that if the frequency of the test voltage Vtest is too low, the first coil may become magnetically saturated and overcurrent may flow in the closed circuit including the first coil when the test voltage Vtest is applied. In addition, when magnetic saturation occurs, the excitation inductance becomes temporarily small, which can reduce the accuracy of excitation inductance estimation. Therefore, the frequency of the test voltage Vtest should be set to a frequency that does not cause magnetic saturation.

In the present embodiment, the frequency setting method of the fundamental wave component of the test voltage Vtest has unique feature. This feature is described below using FIG. 5.

FIG. 5 shows impedance-frequency characteristics of the resonant capacitor and the excitation inductance of the transformer that constitutes the LC series resonant circuit. As shown in an equation (eq1) below, an impedance Zc of the capacitor is higher at lower frequencies. Therefore, the lower the frequency, the harder it is for current to flow through the capacitor. On the other hand, as shown in an equation (eq2) below, an impedance ZL determined from the excitation inductance is lower at lower frequencies. Therefore, the lower the frequency, the easier it is for current to flow through the coil. In the equations below, ω represents each frequency, C represents the capacitance of the capacitor, and L represents the excitation inductance.

$$\begin{matrix}[ Math 1 ] & \\ {Z}_{c} = \frac{1}{j ω C} & ( eq 1 )\end{matrix}$$

$$\begin{matrix}[ Math 2 ] & \\ {Z}_{L} = j ω & ( eq 2 )\end{matrix}$$

A reference frequency fa is a frequency at which the impedance ZL determined from the excitation inductance of the first transformer 60 becomes equal to the impedance Zc of the first resonant capacitor 63. The reference frequency fa should be set, for example, to a value measured in the manufacturing process of the power conversion device 100 or in the inspection process during reuse of the power conversion device 100. In the present embodiment, the reference frequency fa of the first and second transformers 60, 70 is assumed to be the same value. In the estimation process of the excitation inductance of the first transformer 60, the frequency of the fundamental wave component of the test voltage Vtest is set to a frequency lower than the reference frequency fα. In detail, the frequency of the fundamental wave component of the test voltage Vtest is set to the frequency at which the impedance ZL determined from the excitation inductance of the first transformer 60 is less than ⅓ of the impedance Zc of the first resonant capacitor 63. This makes it difficult for current to flow on the second coil 62 side when the test voltage is applied to the first coil 61. As a result, the estimation accuracy of the excitation inductance L1 of the first transformer 60 can be suitably suppressed from being reduced.

In contrast, in a comparative example where the frequency of the fundamental wave component of the test voltage Vtest is set to a frequency higher than the reference frequency fa, when the test voltage is applied to the first coil 61, the current will easily flow to the second coil 62 side. In detail, current flows in a closed loop circuit including the second coil 62, the first resonant capacitor 63, and the body diodes of the switches in the second full-bridge circuit 20, or in a closed loop circuit including the second coil 62, the first resonant capacitor 63, and the first coil 71 of the second transformer 70. As a result, the current detected by the first current sensor 13 is larger than in the present embodiment. This reduces the accuracy of the estimation of the excitation inductance L1 of the first transformer 60. In addition, the distribution of current causes losses.

Note that in the estimation process of the excitation inductance of the first transformer 60, it is desirable that the frequency of the fundamental wave component of the test voltage Vtest be set to a frequency at which the impedance ZL determined from the excitation inductance is ⅕ or less of the impedance Zc of the first resonant capacitor 63 or 1/10 or less.

On the other hand, the reference frequency fa is a frequency at which the impedance ZL determined from the excitation inductance of the second transformer 70 becomes equal to the impedance Zc of the second resonant capacitor 64. In the estimation process of the excitation inductance of the second transformer 70, the frequency of the fundamental wave component of the test voltage Vtest is set to a frequency lower than the reference frequency fa. In detail, the frequency of the fundamental wave component of the test voltage Vtest is set to the frequency at which the impedance ZL determined from the excitation inductance of the second transformer 70 is less than ⅓ of the impedance Zc of the second resonant capacitor 64. This makes it difficult for current to flow on the second coil 72 side when the test voltage is applied to the first coil 71. As a result, the estimation accuracy of the excitation inductance L2 of the second transformer 70 can be suitably suppressed from being reduced.

Note that in the estimation process of the excitation inductance of the second transformer 70, it is desirable that the frequency of the fundamental wave component of the test voltage Vtest be set to a frequency at which the impedance ZL determined from the excitation inductance is ⅕ or less of the impedance Zc of the first and second resonant capacitors 63, 64 or 1/10 or less.

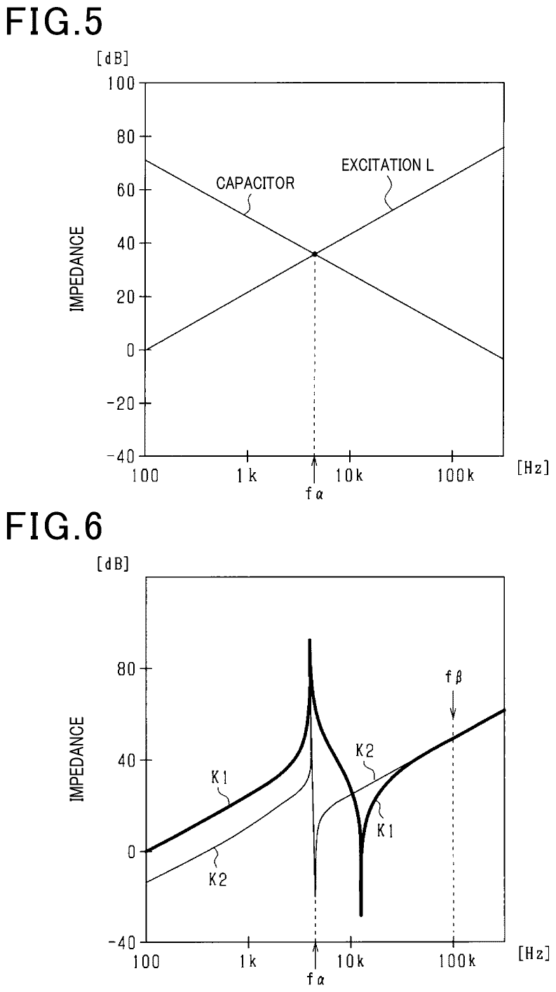

FIG. 6 shows impedance-frequency characteristics K1 of the first closed-loop circuit and impedance-frequency characteristics K2 of the second closed-loop circuit. 1 is calculated from the impedance (Vdc1/I1) calculated based on the detected value of Vdc1 of the first voltage sensor 12 and I1 of the first current sensor 13 when the test voltage Vtest is applied in the condition shown in FIG. 2. K2 is calculated from the impedance (Vdc2/I2) calculated based on the detected value of Vdc2 of the second voltage sensor 22 and 12 of the second current sensor 23 when the test voltage Vtest is applied in the condition shown in FIG. 4. It is assumed that the first and second transformers 60, 70 have the same excitation inductance value (e.g., 1.36 mH) when new, whereas the actual excitation inductance of the second transformer 70 decreases due to deterioration (e.g., 250 μH).

When the frequency of the fundamental wave component of the test voltage Vtest in the estimation process is set to the switching frequency fβ during the power transfer process, the inductances of K1 and K2 are equivalent, as shown in FIG. 6. This indicates that the excitation inductance of the first and second transformers 60, 70 is not correctly estimated. In the present embodiment, on the other hand, the frequency of the fundamental wave component is set lower than the reference frequency fα. In this case, the excitation inductance can be estimated correctly.

Note that in the example shown in FIG. 6, the resonant frequency of each closed-loop circuit and the reference frequency fa are the same or equivalent. In the estimation process of the excitation inductance of each transformer 60, 70, the frequency of the fundamental wave component of the test voltage Vtest may be set to a value greater than ⅕ and less than ⅓ of the reference frequency fa, or greater than 1/10 and less than ⅕ of the reference frequency fa.

FIG. 7 shows a flowchart of the excitation inductance estimation process performed by the control device 110.

In step S10, the transformer to be estimated is selected from the first and second transformers 60, 70. In the present embodiment, the first transformer 60 (corresponding to a target element) is first selected for estimation.

In step S11, as shown in FIG. 2, all switches QB1 to QB4 of the second full-bridge circuit 20 are turned off, and all switches QC1 to QC4 of the third full-bridge circuit 30 are turned off.

In step S12, the current test voltage Vtest is obtained, and in step S13, the detection value Itest of the first current sensor 13 when the test voltage Vtest is being applied is obtained.

In step S14, the excitation inductance L1 of the first transformer 60 is estimated based on the acquired test voltage Vtest and current Itest.

In step S15, it is determined whether the estimation of the excitation inductance of both the first and second transformers 60, 70 is completed. If a negative determination is made in step S15, the process proceeds to step S10, and the second transformer 70 (corresponding to a target element) is selected as the target for estimating the exciting inductance. Then, as in the case of the estimation process for the excitation inductance of the first transformer 60, steps S11 to S14 are performed.

If a positive determination is made in step S15, the process proceeds to step S16 to execute the power transfer process.

Note that the selection order of the first and second transformers 60, 70 to be used for estimating the excitation inductance is not limited to a specific order, such as selecting the first transformer 60 and then the second transformer 70, and may be changed as needed.

FIG. 8 shows the results of the excitation inductance estimation process in each of the present embodiment and the comparative example. In the example shown in FIG. 8, the true values of the excitation inductances of the first and second transformers 60, 70 are the same. According to present embodiment, the estimated values of the excitation inductance of the first and second transformers 60, 70 result close to the true value. In contrast, in the comparative example, the frequency of the fundamental wave component of the test voltage Vtest is set to a frequency higher than the reference frequency fα, so that the first coil 71 of the second transformer 70 is equivalently connected in parallel to the second coil 62 of the first transformer 60. As a result, the estimated value of the excitation inductance of the first and second transformers 60, 70 is about ½ of the true value, which greatly reduces the accuracy of the estimation.

According to the present embodiment described in detail above, the estimation accuracy of the transformer excitation inductance can be suitably suppressed from being reduced.

### Modification of First Embodiment

The first resonant capacitor 63 may be connected in series with the first coil 61 instead of the second coil 62 of the first transformer 60.
The second resonant capacitor 64 may be connected in series with the first coil 71 instead of the second coil 72 of the second transformer 70.
The switching frequency fsw of each switch QA1 to QA4, QB1 to QB4, and QC1 to QC4 may be set to a frequency lower than the lower of the resonant frequencies of the first and second closed loop circuits.
The estimation process shown in FIG. 7 may be performed immediately after the startup of the control device 110, or it may be performed during a period other than immediately after startup, as long as it is outside the period of execution of the power transfer process.
For example, in the estimation process performed immediately after the startup of the control device 110, the transformers subject to the estimation of the excitation inductance are not limited to all transformers provided by the power conversion device 100, but may be some of them. In this case, some of the transformers to be estimated may be changed each time the control device 110 is started.
If the control device 110 determines that the estimated value of the excitation inductance is out of its normal range, it may determine that the transformer corresponding to the estimated value that is out of the normal range is faulty. In this case, the control device 110 may prohibit the execution of the power transfer process or notify the user that an abnormality has occurred. Here, the notification process can be, for example, a process to notify the user by controlling a notification unit (e.g., a sound generator such as a buzzer, a light generator such as an electric light) provided by the system.
The control device 110 may disconnect the electrical connection between the electrical load connected to each external terminal and each external terminal prior to performing the estimation process.
The energy loss generated by the switching control of the full-bridge circuit in the estimation process and the current flowing through the full-bridge circuit during the estimation process may be large compared to the electrostatic energy stored in the capacitor on the external terminal side of the full-bridge circuit (for example, the first capacitor 11 in the circuit state of FIG. 2). In this case, the control device 110 may control the supply of the power required during the estimation process to the capacitor from a voltage source connected to an external terminal.

### Second Embodiment

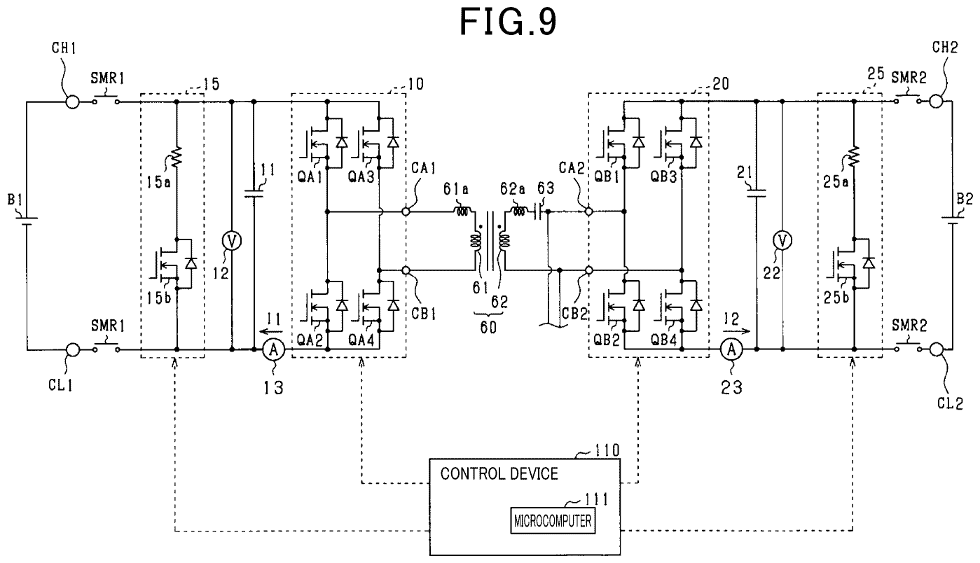

The second embodiment is described below with reference to the drawings, focusing on the differences from the first embodiment. In the present embodiment, as shown in FIG. 9, a power conversion device 100 includes a first voltage adjustment circuit 15 and a second voltage adjustment circuit 25. Note that in FIG. 9, a third full-bridge circuit 30 and other circuits are omitted for convenience.

In the present embodiment, the first voltage adjustment circuit 15 is a discharge circuit for a first capacitor 11, with a series connection of a first discharge resistor 15a and a first discharge switch 15b. The second voltage adjustment circuit 25 is also a discharge circuit for a second capacitor 21, with a series connection of a second discharge resistor 25a and a second discharge switch 25b. The first voltage adjustment circuit 15 is connected in parallel to the first capacitor 11, and the second voltage adjustment circuit 25 is connected in parallel to the second capacitor 21. In the present embodiment, each of the voltage adjustment circuits 15, 25 is used to suppress magnetic saturation of the transformer from occurring during the estimation process.

The power conversion device 100 includes a first disconnect switch SMR1 (e.g., relay) for electrically connecting or disconnecting a first high potential side terminal CH1 and a first low potential side terminal CL1 with the first voltage regulating circuit 15. Further, the power conversion device 100 includes a second disconnect switch SMR2 (e.g., relay) for electrically connecting or disconnecting a second high potential side terminal CH2 and a second low potential side terminal CL2 with the second voltage regulating circuit 25. FIG. 9 shows an example where a first storage battery B1 is connected to the first high potential side terminal CH1 and the first low potential side terminal CL1, and a second storage battery B2 is connected to the second high potential side terminal CH2 and the second low potential side terminal CL2.

The control device 110 discharges the electric charge from the first capacitor 11 by controlling the first discharge switch 15b with the first disconnect switch SMR1 turned off. This makes the terminal voltage of the first capacitor 11 during the process of estimating the excitation inductance of a first transformer 60 lower than the terminal voltage of the first capacitor 11 during the power transfer process (specifically, a rated voltage). As a result, the amplitude of the fundamental wave component of the test voltage Vtest during the estimation process becomes smaller than the amplitude of the fundamental wave component of the voltage output from a first full-bridge circuit 10 during the power transfer process.

The frequency of the fundamental wave component of the test voltage Vtest during the estimation process is set to a low frequency as described above. Therefore, magnetic saturation of the first transformer 60 is likely to occur. If magnetic saturation occurs, there is a concern that overcurrent will flow in the closed loop circuit including the first full-bridge circuit 10 and a first coil 61. Therefore, by reducing the amplitude of the fundamental wave component of the test voltage Vtest, magnetic saturation of the first transformer 60 is suppressed from occurring.

Similarly, the control device 110 discharges the electric charge from the second capacitor 21 by controlling the second discharge switch 25b with the second disconnect switch SMR2 turned off. This makes the terminal voltage of the second capacitor 21 during the process of estimating the excitation inductance of a second transformer 70 lower than the terminal voltage of the second capacitor 21 during the power transfer process.

Note that if the terminal voltages of the first and second capacitors 11, 21 are reduced too much during the estimation process, the change in the current flowing through the transformer coils will become small, and the accuracy of the excitation inductance estimation may decrease. Therefore, the terminal voltages of the first and second capacitors 11, 21 should be set to values that take into account the prevention of magnetic saturation and the securing of estimation accuracy during the estimation process.

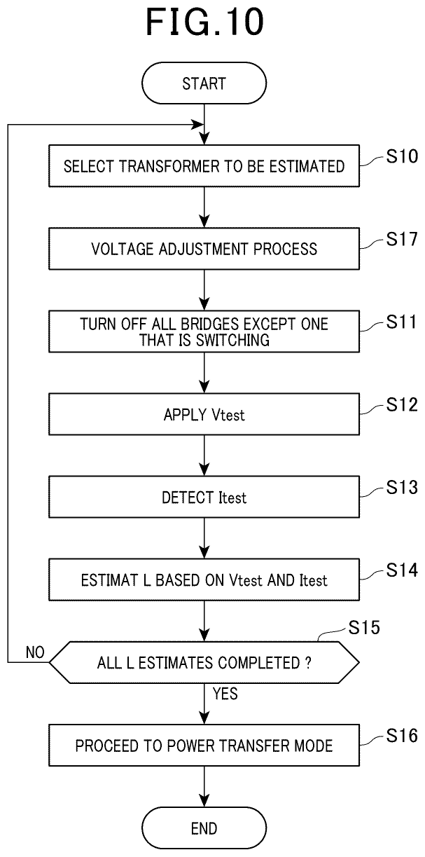

FIG. 10 shows a flowchart of the excitation inductance estimation process performed by the control device 110. In FIG. 10, the same processes as those shown in FIG. 7 above are given the same reference numerals for convenience.

After completion of the process in step S10, the process proceeds to step S17. When the first transformer 60 is selected as the estimation target, step S17 discharges the charge from the first capacitor 11 by controlling the first discharge switch 15b with the first disconnect switch SMR1 turned off. This makes the amplitude of the fundamental wave component of the test voltage Vtest in step S12 smaller than the amplitude of the fundamental wave component of the voltage output from the first full-bridge circuit 10 during the power transfer process.

When the second transformer 70 is selected as the estimation target, step S17 discharges the charge from the second capacitor 21 by controlling the second discharge switch 25b with the second disconnect switch SMR2 turned off. This makes the amplitude of the fundamental wave component of the test voltage Vtest in step S12 smaller than the amplitude of the fundamental wave component of the voltage output from the second full-bridge circuit 20 during the power transfer process.

According to the present embodiment described above, magnetic saturation of the transformer during the estimation process can be suppressed from occurring.

### Modification of Second Embodiment

The voltage adjustment circuit that adjusts the terminal voltage of the capacitor is not limited to a discharge circuit, but may be a DC-DC converter, for example.
When performing the estimation process in the circuit state shown in FIG. 2, the control device 110 may control the first discharge switch 15b so as to make the terminal voltage of the second capacitor 21 higher than the value obtained by multiplying the terminal voltage of the first capacitor 11 by the turn's ratio of the first transformer 60. This prevents current from flowing in the closed loop circuit including the second coil 62, the first resonant capacitor 63, and the body diodes of the switches in the second full-bridge circuit 20 when the test voltage Vtest is applied to the first coil 61.

When performing the estimation process in the circuit state shown in FIG. 4, the control device 110 may control the second discharge switch 25b so as to make the terminal voltage of the third capacitor 31 higher than the value obtained by multiplying the terminal voltage of the second capacitor 21 by the turn's ratio of the second transformer 70. In addition, when the control device 110 performs the estimation process in the circuit state shown in FIG. 4, the control device 110 may control the second discharge switch 25b so as to make the terminal voltage of the first capacitor 11 higher than the value obtained by multiplying the terminal voltage of the second capacitor 21 by the turn's ratio of the first transformer 60.

In the process shown in FIG. 10, voltage adjustment was performed in step S17 each time a transformer to be estimated is selected in step S10, but it is not limited to this. For example, voltage adjustment may be performed for all of the first, second and third capacitors 11, 21, 31 at the beginning of the process shown in FIG. 10.

### Third Embodiment

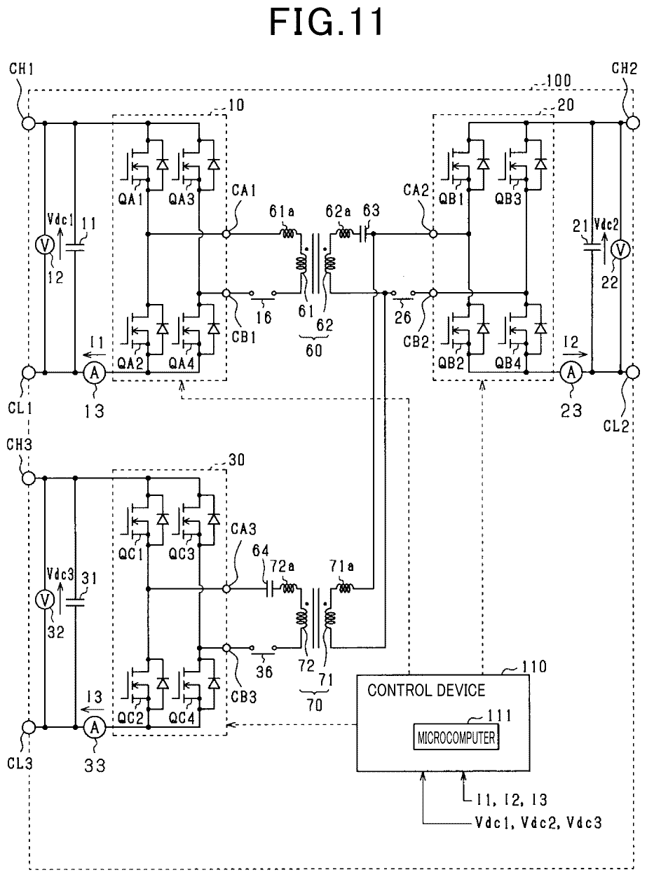

The third embodiment is described below with reference to the drawings, focusing on the differences from the first embodiment. As shown in FIG. 11, a power conversion device 100 includes a first switch 16, a second switch 26, and a third switch 36. Each of the switches 16, 26, 36 in the present embodiment is a relay. The first switch 16 is disposed in an electrical path from a first-A AC terminal CA1 to a first-B AC terminal CB1 via a first coil 61. The second switch 26 is disposed in an electrical path from a second-A AC terminal CA2 to a second-B AC terminal CB2 via a first resonant capacitor 63 and a second coil 62. The third switch 36 is disposed in an electrical path from a third-A AC terminal CA3 to a third-B AC terminal CB3 via a second resonant capacitor 64 and a second coil 72.

When the control device 110 performs the estimation process in the circuit state shown in FIG. 2, it turns on the first switch 16 and turns off the second switch 26 and the third switch 36. This makes it possible to prevent current from flowing through a closed loop circuit including the second coil 62, the first resonant capacitor 63, and a body diode of the second full bridge circuit 20, and through a closed loop circuit including the second coil 72, the second resonant capacitor 64, and a body diode of the third full bridge circuit 30, when a test voltage Vtest is applied to the first coil 61.

When the control device 110 performs the estimation process in the circuit state shown in FIG. 4, it turns on the second switch 26 and turns off the first switch 16 and the third switch 36. This makes it possible to prevent current from flowing through a closed loop circuit including the first coil 61 and a body diode of the first full bridge circuit 10, and through a closed loop circuit including the second coil 72, the second resonant capacitor 64, and a body diode of the third full bridge circuit 30, when a test voltage Vtest is applied to the first coil 71.

### Fourth Embodiment

The fourth embodiment is described below with reference to the drawings, focusing on the differences from the first embodiment.

As shown in FIG. 6 earlier, peaks appear in the impedance frequency response due to the LC resonance of the LC series resonant circuit. In the example shown in FIG. 6, peaks appear around 5 kHz to 10 kHz. Note that FIG. 6 shows the impedance-frequency characteristics of a 3-port power conversion device, but as the number of ports increases, the number of peaks that appear also increases.

When the test voltage Vtest in the excitation inductance estimation process is a square wave voltage, the square wave contains harmonic components. As a result, the frequencies of the harmonic components are at or near the resonant frequency of the LC resonance, and a resonant current flows. In this case, there is a concern that the accuracy of the excitation inductance estimation may be reduced or that an overcurrent may flow to the transformer coils, etc.

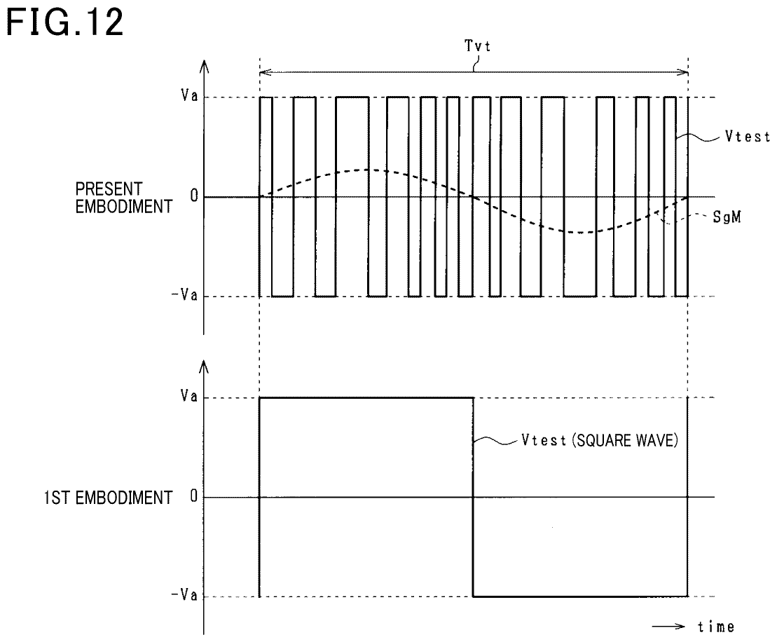

Therefore, as shown in the upper part of FIG. 12, a control device 110 outputs the test voltage Vtest from a full-bridge circuit by controlling the switching of the full-bridge circuit at a switching frequency higher than the resonant frequency of first and second closed loop circuits (e.g., 100 kHz) during the estimation process. In detail, the control device 110 controls the switching of the full-bridge circuit by PWM processing based on a large/small comparison between the carrier signal SgC, which is a triangular wave, and the modulation wave SgM, which is a sine wave. The modulation wave SgM is a signal with a frequency lower than the resonant frequency (e.g., 1 kHz), and the carrier signal SgC is a signal with a switching frequency higher than the resonant frequency of the first and second closed loop circuits. This avoids the frequency of harmonic components in the test voltage Vtest to be at or near the resonant frequency, thus avoiding the distribution of resonant current. Note that Tvt in FIG. 12 represents one period of the fundamental wave component of the test voltage Vtest.

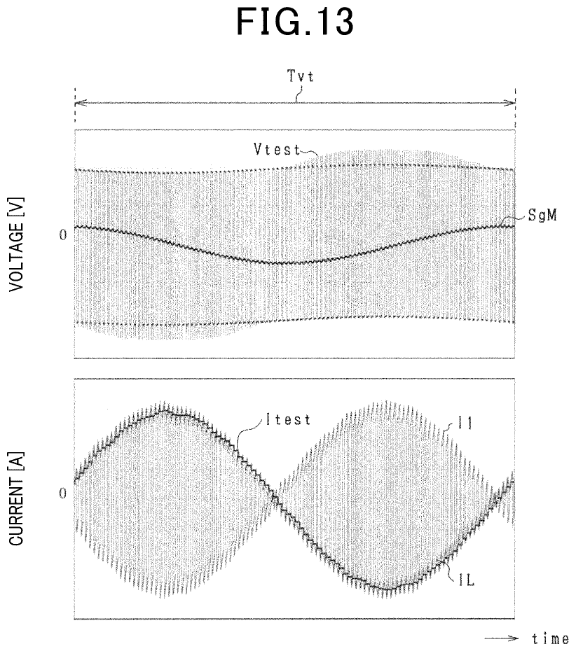

Taking the estimation process of the excitation inductance of a first transformer 60 as an example, when the above PWM process is performed, the current I1 detected by a first current sensor 13 will include a high frequency ripple, as shown in FIG. 13. On the other hand, the current IL flowing in a first coil 61 of the first transformer 60 will be significantly different from the waveform of the current I1 detected by the first current sensor 13.

Therefore, the control device 110 uses the timing when the carrier signal SgC is at its minimum value or when the carrier signal is at its maximum value as the current sampling timing by the first current sensor 13. Thereby the detected value Itest of the first current sensor 13 used to estimate the excitation inductance is close to the current IL flowing in the first coil 61. As a result, it becomes possible to suppress the estimation accuracy of the excitation inductance from being reduced.

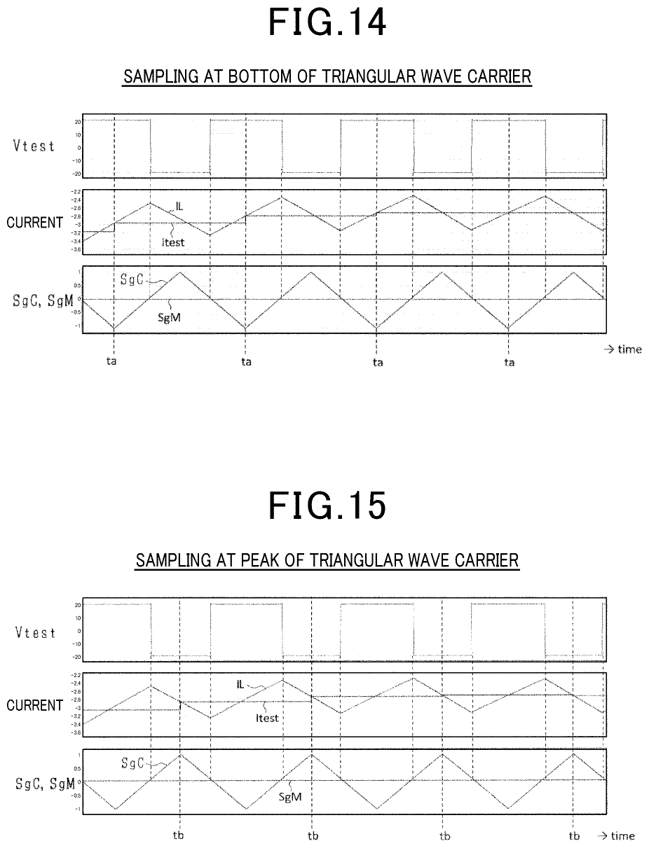

FIG. 14 shows an example of current sampling at timing ta, when the carrier signal SgC is at its minimum value, and FIG. 15 shows an example of current sampling at timing tb, when the carrier signal SgC is at its maximum value. FIGS. 14 and 15 show changes in the test voltage Vtest, the current IL flowing through the first coil 61 of the first transformer 60, the current Itest detected by the first current sensor 13, the carrier signal SgC, and the modulated wave SgM.

According to the current sampling timing explained above, it is possible to detect values near the median of the current IL flowing in the first coil 61, including current ripple. As a result, it becomes possible to suppress the estimation accuracy of the excitation inductance from being reduced.

### Fifth Embodiment

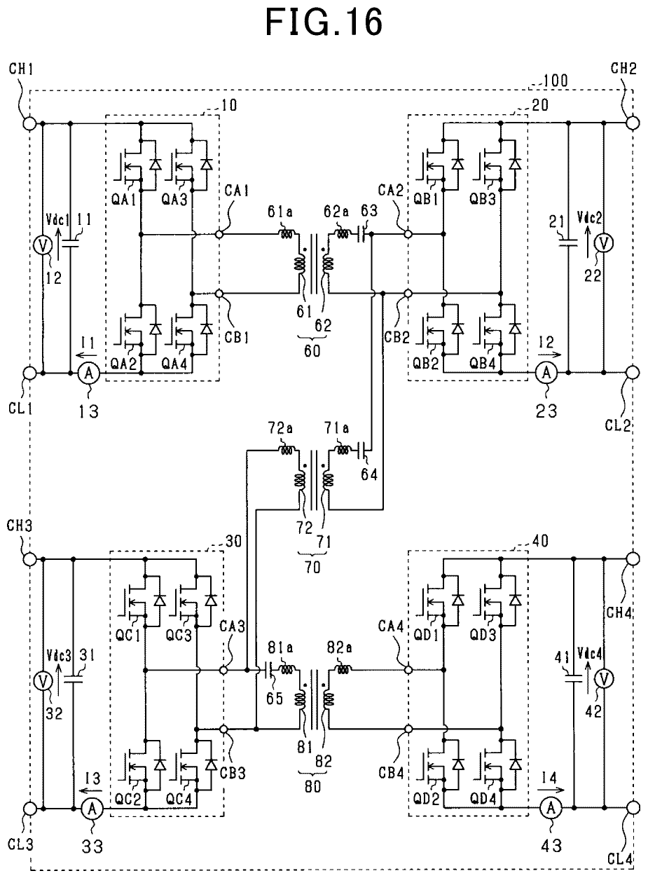

The fifth embodiment is described below with reference to the drawings, focusing on the differences from the first embodiment. The number of ports on a power conversion device 100 is not limited to three, but may be as many as four, as shown in FIG. 16. Note that in FIG. 16, a control device 110 and other devices are omitted for convenience.

The power conversion device 100 includes a fourth high potential side terminal CH4 and a fourth low potential side terminal CL4 as the fourth external terminals. The power conversion device 100 also includes a fourth full-bridge circuit 40 and a fourth capacitor 41. The fourth full-bridge circuit 40 includes first-D to fourth-D switches QD1 to QD4. In the present embodiment, the first-D to fourth-D switches QD1 to QD4 are N-channel MOSFETs and have body diodes. In the present embodiment, since the configuration of the fourth full-bridge circuit 40 is similar to that of the first full-bridge circuit 10, a detailed description of the fourth full-bridge circuit 40 is omitted.

Note that in the present embodiment, a second resonant capacitor 64 is connected in series with a first coil 71 of a second transformer 70.

The power conversion device 100 includes a third transformer 80 and a third resonant capacitor 65 as a configuration for transferring power between the third full-bridge circuit 30 and the fourth full-bridge circuit 40. The third transformer 80 includes a first coil 81, a second coil 82, and a core around which the first and second coils 81 and 82 are wound. The first coil 81 and the second coil 82 are magnetically coupled through the core.

A first end of the first coil 81 is connected to a third-A AC terminal CA3 via the third resonant capacitor 65. A second end of the first coil 81 is connected to a third-B AC terminal CB3. A first end of the second coil 82 is connected to a fourth-A AC terminal CA4 of the fourth full-bridge circuit 40. A second end of the second coil 82 is connected to a fourth-B AC terminal CB4 of the fourth full-bridge circuit 40. Note that FIG. 16 also shows leakage inductances 81a and 82a of the first and second coils 81 and 82 together.

The power conversion device 100 includes a fourth voltage sensor 42 and a fourth current sensor 43. The fourth voltage sensor 42 detects the voltage of the fourth capacitor 41.

The fourth current sensor 43 detects the current flowing between the fourth full-bridge circuit 40 and the fourth low potential side terminal CL4. The detected value Vdc4 of the fourth voltage sensor 42 and the detected value 14 of the fourth current sensor 43 are input to the control device 110.

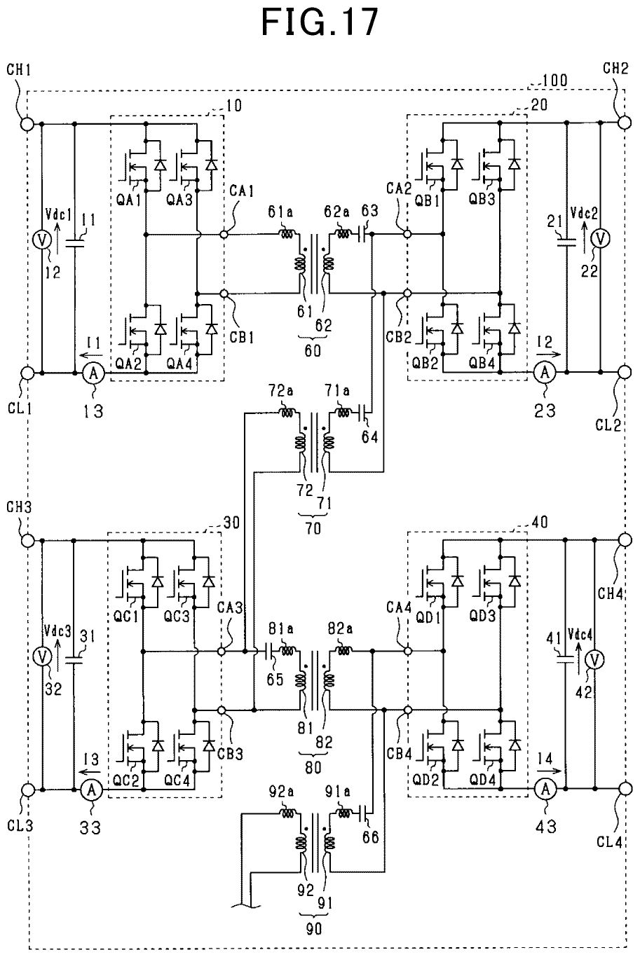

Note that as shown in FIG. 17, the number of ports of a power conversion device 100 may be five or more. In this case, the power conversion device 100 should have at least a fourth transformer 90 with a first coil 91 and a second coil 92 and a fourth resonant capacitor 66. Note that FIG. 17 also shows leakage inductances 91a and 92a of the first and second coils 91 and 92 together.

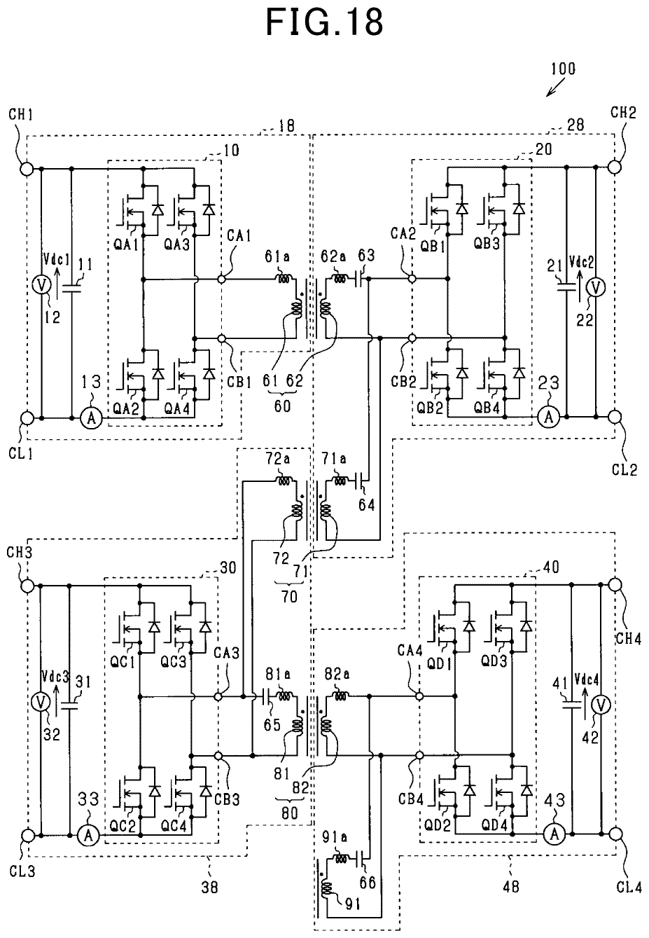

In addition, the configuration shown in FIG. 17 can also be modified as shown in FIG. 18. A power conversion device 100 has a first module 18, a second module 28, a third module 38, and a fourth module 48. The first module 18 is a modularized device consisting of a first full-bridge circuit 10, a first capacitor 11, a first coil 61, a part of a core of a first transformer 60, a first voltage sensor 12, and a first current sensor 13 accommodated in a first housing. The second module 28 is a modularized device consisting of a second full-bridge circuit 20, a second capacitor 21, a second coil 62, a part of the core of the first transformer 60, a first coil 71 a part of a core of a second transformer 70, a second resonant capacitor 64, a second voltage sensor 22, and a second current sensor 23 accommodated in a second housing.

A portion of the core around which the first coil 61 of the first transformer 60 is wound is exposed from a surface of the first housing of the first module 18 that is in contact with the second housing of the second module 28. In addition, a portion of the core around which the second coil 62 of the first transformer 60 is wound is exposed from a surface of the second housing of the second module 28 that is in contact with the first housing of the first module 18. When the contacting surface of the first housing contacts against the contacting surface of the second housing, the first and second housings are integrated together, so that the portion of the core around which the first coil 61 of the first transformer 60 is wound contacts against the portion of the core around which the second coil 62 of the first transformer 60 is wound. This causes magnetic coupling between the first coil 61 and the second coil 62 in the first transformer 60.

The third module 38 is a modularized device consisting of a third full-bridge circuit 30, a third capacitor 31, a second coil 72, a part of a core of a second transformer 70, a first coil 81, a part of a core of a third transformer 80, a third resonant capacitor 65, a third voltage sensor 32, and a third current sensor 33 accommodated in a third housing.

A portion of the core around which the first coil 71 of the second transformer 70 is wound is exposed from a surface of the second housing of the second module 28 that is in contact with the third housing of the third module 38. In addition, a portion of the core around which the second coil 72 of the second transformer 70 is wound is exposed from a surface of the third housing of the third module 38 that is in contact with the second housing of the second module 28. When the contacting surface of the second housing contacts against the contacting surface of the third housing, the second and third housings are integrated together, so that the portion of the core around which the first coil 71 of the second transformer 70 is wound contacts against the portion of the core around which the second coil 72 of the second transformer 70 is wound. This causes magnetic coupling between the first coil 71 and the second coil 72 in the second transformer 70.

The fourth module 48 is a modularized device consisting of a fourth full-bridge circuit 40, a fourth capacitor 41, a second coil 82, a part of the core of a third transformer 80, a first coil 91, a part of a core of a fourth transformer 90, a fourth resonant capacitor 66, a fourth voltage sensor 42, and a fourth current sensor 43 accommodated in a fourth housing.

A portion of the core around which the first coil 81 of the third transformer 80 is wound is exposed from a surface of the third housing of the third module 38 that is in contact with the fourth housing of the fourth module 48. In addition, a portion of the core around which the second coil 82 of the third transformer 80 is wound is exposed from a surface of the fourth housing of the fourth module 48 that is in contact with the third housing of the third module 38. When the contacting surface of the third housing contacts against the contacting surface of the fourth housing, the third and fourth housings are integrated together, so that the portion of the core around which the first coil 81 of the third transformer 80 is wound contacts against the portion of the core around which the second coil 82 of the third transformer 80 is wound. This causes magnetic coupling between the first coil 81 and the second coil 82 in the third transformer 80.

According to the configuration shown in FIG. 18, the power conversion device 100 can be implemented according to the number of ports, etc. desired by the user. Note that in the configuration shown in FIG. 18, one of the modules 18, 28, 38, 48 should be a master module that determines the order of estimation of the excitation inductance of the transformer, etc.

### Other Embodiments

Each of the above embodiments may be implemented with the following modifications.

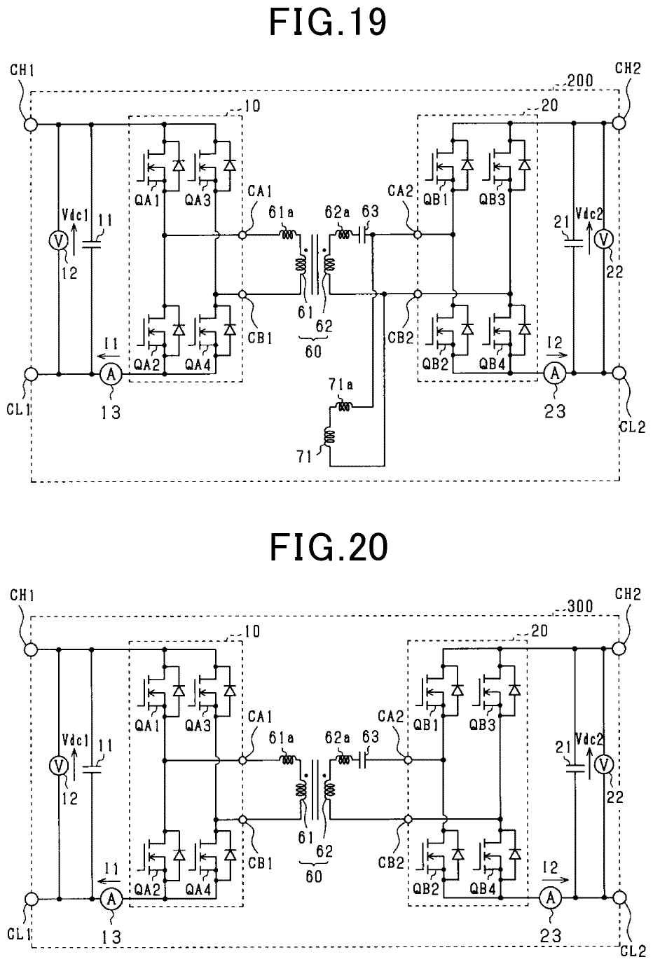

As shown in FIG. 19, a power conversion device 200 may have two ports. Even in this case, the frequency of the fundamental wave component of the test voltage Vtest output from a first full-bridge circuit 10 is set to a frequency lower than the reference frequency fa, thereby preventing a decline in the estimation accuracy of the excitation inductance. Note that in the configuration shown in FIG. 19, a first coil 71 corresponds to a second inductance element.

Switches that the full-bridge circuit has are not limited to N-channel MOSFETs, but can be, for example, IGBTs with freewheeling diodes connected in reverse parallel. In this case, a high potential side terminal of a switch is a collector and a low potential side terminal of the switch is an emitter.

As shown in FIG. 20, a power conversion device 300 may have two ports.

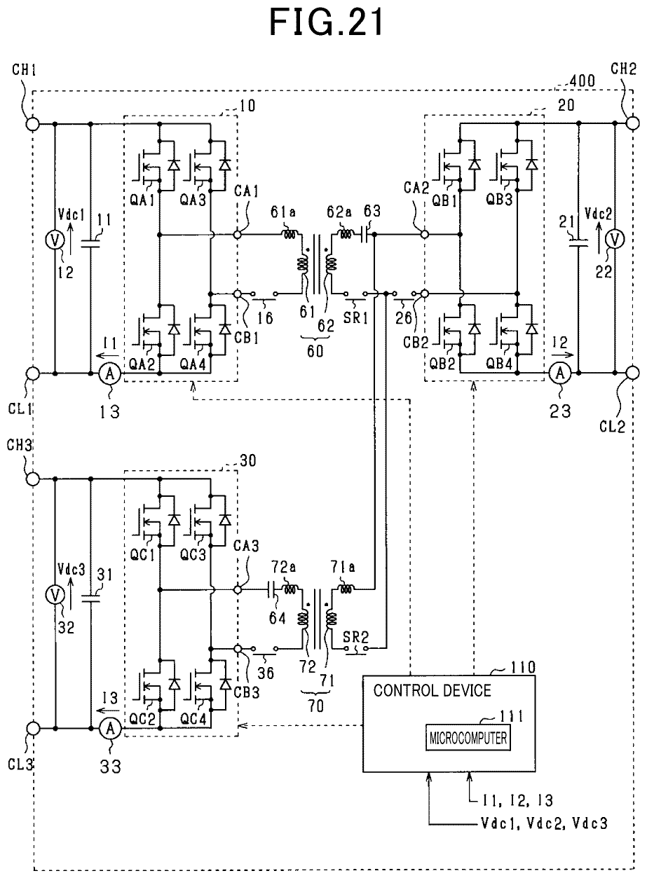

As shown in FIG. 21, a power conversion device 400 may include relays SR1 and SR2 so that current flows only through a coil of a transformer to be estimated.

In the estimation process of each of the above embodiments, the frequency of the fundamental wave component of the test voltage Vtest may be set to a higher frequency than the reference frequency fα.

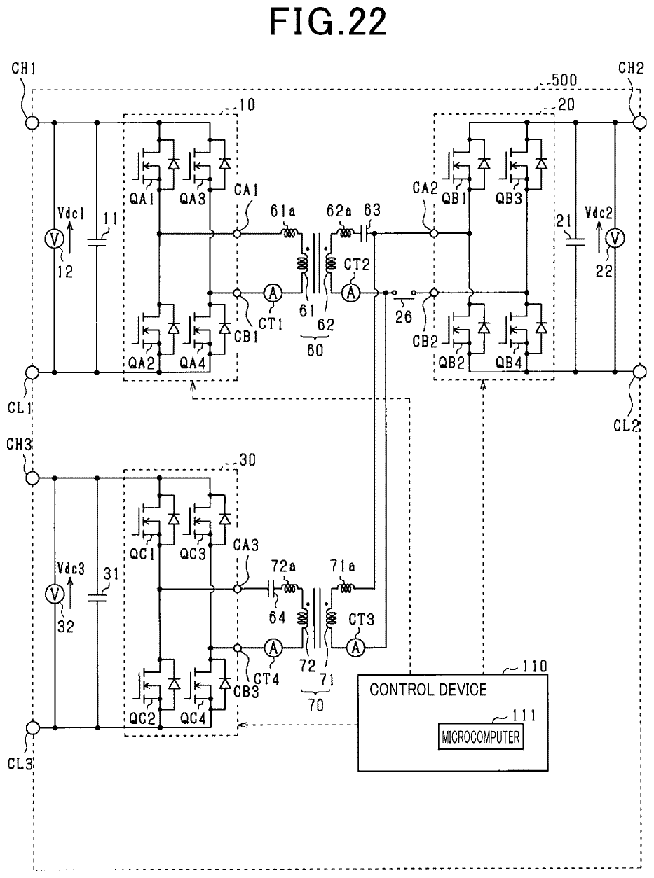

As shown in FIG. 22, a power conversion device 500 may include current sensors CT1, CT2, CT3, and CT4 that individually detect the current flowing in each coil 61, 62, 71, 72. In this case, the frequency of the fundamental wave component of the test voltage Vtest may be set to a higher frequency than the reference frequency fa in the estimation process.

A bridge circuit is not limited to a full-bridge circuit, but may be any other bridge circuit as long as it can output a voltage (e.g., AC voltage) with alternating polarity reversal to transformer coils.

A control unit and methods described in the present disclosure may be realized by a dedicated computer provided by configuring a processor and memory programmed to perform one or more functions embodied by the computer program. Alternatively, the control section and methods described in the present disclosure may be realized by a dedicated computer provided by configuring the processor with one or more dedicated hardware logic circuits. Alternatively, the control section and methods described in the present disclosure may be realized by one or more dedicated computers composed of a processor and memory programmed to perform one or more functions, in combination with a processor composed of one or more hardware logic circuits. In addition, the computer program may also be stored in a computer-readable, non-transitory tangible storage media as instructions to be executed by a computer.

Although the present disclosure has been described in accordance with examples, it is understood that the present disclosure is not limited to the examples or structures. The present disclosure also encompasses various variants and variations within the scope of equality. In addition, various combinations and forms, as well as other combinations and forms that include only one element, more or less, thereof, also fall within the scope and idea of the present disclosure.

What is claimed is:

1. A power conversion device comprising:
a first circuit, which is a bridge circuit connected to a first external terminal,
a second circuit, which is a bridge circuit connected to a second external terminal,
an inductance element connecting a first AC terminal of the first circuit and a second AC terminal of the second circuit,
a resonant capacitor connected to the inductance element, and
a control unit, wherein
the control unit performs:
a power transfer process to transfer power between the first external terminal and the second external terminal via the inductance element by switching control of at least one of the first circuit and the second circuit, and
an estimation process to estimate an inductance of the inductance element by outputting a test voltage to the inductance element, wherein
a frequency of a fundamental wave component of the test voltage is set to a frequency lower than a frequency of a fundamental wave component of a voltage output to the inductance element in the power transfer process.

2. The power conversion device according to claim 1, wherein
there is provided a first transformer with a first coil connected to the first AC terminal and a second coil connected to the second AC terminal as the inductance element,
the resonant capacitor is a first resonant capacitor connected in series with the first coil or the second coil,
there is provided a third circuit, which is a bridge circuit connected to a third external terminal,
a second transformer including a third coil connected to the second AC terminal and a fourth coil connected to the third AC terminal of the third circuit, and
a second resonant capacitor connected in series with the fourth coil, wherein
the power transfer process is a process of transferring power between at least two of the first external terminal, the second external terminal, and the third external terminal by switching control of at least one of the first circuit, the second circuit, and the third circuit,
the control unit performs:
acquiring an estimation current which is a current flowing through a path on the second external terminal side relative to the second AC terminal among a current flow path from the second external terminal through the second circuit to the third coil, and
estimating, in the estimation process, an excitation inductance of the second transformer based on the test voltage and the acquired current for estimation when the test voltage is output from the second AC terminal by switching control of the second circuit, wherein
a frequency of a fundamental wave component of the test voltage is set to a frequency lower than a frequency of a fundamental wave component of a voltage output from the second AC terminal in the power transfer process.

3. The power conversion device according to claim 2, wherein
the current for estimation is a second estimation current, and
the first resonant capacitor is connected in series with the second coil,
the control unit performs:
acquiring a first estimation current which is a current flowing through a path on the first external terminal side relative to the first AC terminal among a current flow path from the first external terminal through the first circuit to the first coil, and
estimating, in the estimation process, an excitation inductance of the first transformer based on the test voltage and the first estimation current when the test voltage is output from the first AC terminal by switching control of the first circuit,

4. A power conversion device comprising:
a first circuit, which is a bridge circuit connected to a first external terminal,
a second circuit, which is a bridge circuit connected to a second external terminal,
a third circuit, which is a bridge circuit connected to a third external terminal,
a first transformer with a first coil connected to a first AC terminal of the first circuit and a second coil connected to a second AC terminal of the second circuit,
a first resonant capacitor connected in series with the second coil,
a second transformer with a third coil connected to the second AC terminal and a fourth coil connected to a third AC terminal of the third circuit,
a second resonant capacitor connected in series with the third or fourth coil, and
a control unit, wherein
the control unit performs:
a power transfer process to transfer power between at least two of the first external terminal, the second external terminal, and the third external terminal by switching control of at least one of the first circuit, the second circuit, and the third circuit,
an estimation process to estimate an excitation inductance of the first transformer,
acquiring an estimation current which is a current flowing through a path on the first external terminal side relative to the first AC terminal among a current flow path from the first external terminal through the first circuit to the first coil, and
estimating, in the estimation process, an excitation inductance of the first transformer based on the test voltage and the acquired current for estimation when the test voltage is output from the first AC terminal by switching control of the first circuit, wherein
a frequency of a fundamental wave component of the test voltage is set to a frequency lower than a frequency of a fundamental wave component of a voltage output from the first AC terminal in the power transfer process.

5. The power conversion device according to claim 1, wherein
there is provided a transformer with a first coil connected to the first AC terminal and a second coil connected to the second AC terminal as the inductance element,
the resonant capacitor is connected in series with the second coil, and
there is provided a third coil connected to the second AC terminal, wherein
the power transfer process is a process of transferring power between the first external terminal and the second external terminal by switching control of at least one of the first circuit and the second circuit,
the control unit estimates, in the estimation process, an excitation inductance of the transformer based on the test voltage and a current for estimation, which is a current flowing in the first coil, when the test voltage is output from the first AC terminal by the switching control of the first circuit, and
a frequency of a fundamental wave component of the test voltage is set to a frequency lower than a frequency of a fundamental wave component of a voltage output from the first AC terminal in the power transfer process.

6. The power conversion device according to claim 2, wherein
the frequency of the fundamental wave component of the test voltage in a case of estimating the excitation inductance of the second transformer is set to a frequency at which the impedance determined from the excitation inductance of the second transformer is smaller than the impedances of the first resonant capacitor and the second resonant capacitor.

7. The power conversion device according to claim 6, wherein
the frequency of the fundamental wave component of the test voltage in the case of estimating the excitation inductance of the second transformer is set to a frequency at which the impedance determined from the excitation inductance of the second transformer is less than ⅓ of the impedances of the first resonant capacitor and the second resonant capacitors.

8. The power conversion device according to claim 3, wherein
the frequency of the fundamental wave component of the test voltage in a case of estimating the excitation inductance of the first transformer is set to a frequency at which the impedance determined from the excitation inductance of the first transformer is smaller than the impedance of the first resonant capacitor.

9. The power conversion device according to claim 8, wherein
the frequency of the fundamental wave component of the test voltage in the case of estimating the excitation inductance of the first transformer is set to a frequency at which the impedance determined from the excitation inductance of the first transformer is less than ⅓ of the impedance of the first resonant capacitor.

10. A power conversion device comprising:
a first circuit, which is a bridge circuit connected to a first external terminal,
a second circuit, which is a bridge circuit connected to a second external terminal,
a third circuit, which is a bridge circuit connected to a third external terminal,
a first transformer with a first coil connected to a first AC terminal of the first circuit and a second coil connected to a second AC terminal of the second circuit,
a first resonant capacitor connected in series with the first coil or the second coil,
a second transformer with a third coil connected to the second AC terminal and a fourth coil connected to a third AC terminal of the third circuit,
a second resonant capacitor connected in series with the fourth coil, and
a control unit, wherein
the control unit performs:
acquiring an estimation current which is a current flowing through a path on the second external terminal side relative to the second AC terminal among a current flow path from the second external terminal through the second circuit to the third coil, and
estimating an excitation inductance of the second transformer based on the test voltage and the acquired current for estimation when the test voltage is output from the second AC terminal by switching control of the second circuit, wherein
a frequency of the fundamental wave component of the test voltage in a case of estimating the excitation inductance of the second transformer is set to a frequency at which the impedance determined from the excitation inductance of the second transformer is smaller than the impedances of the first capacitor and the second resonant capacitor.

11. A power conversion device comprising:
a first circuit, which is a bridge circuit connected to a first external terminal,
a second circuit, which is a bridge circuit connected to a second external terminal,
a third circuit, which is a bridge circuit connected to a third external terminal,
a first transformer with a first coil connected to a first AC terminal of the first circuit and a second coil connected to a second AC terminal of the second circuit,
a first resonant capacitor connected in series with the second coil,
a second transformer with a third coil connected to the second AC terminal and a fourth coil connected to a third AC terminal of the third circuit,
a second resonant capacitor connected in series with the third or fourth coil, and
a control unit, wherein
the control unit performs:
acquiring an estimation current which is a current flowing through a path on the first external terminal side relative to the first AC terminal among a current flow path from the first external terminal through the first circuit to the first coil, and
estimating an excitation inductance of the first transformer based on the test voltage and the acquired current for estimation when the test voltage is output from the first AC terminal by switching control of the first circuit, wherein
a frequency of the fundamental wave component of the test voltage in a case of estimating the excitation inductance of the first transformer is set to a frequency at which the impedance determined from the excitation inductance of the first transformer is smaller than the impedance of the first capacitor.

12. The power conversion device according to claim 2, wherein
the control unit reduces an amplitude of the fundamental wave component in the estimation process to less than an amplitude of the fundamental wave component of the output voltage in the power transfer process.

13. The power conversion device according to claim 12, wherein
there is provided a voltage adjustment circuit that adjusts at least one of an input voltage on the first external terminal side of the first circuit and an input voltage on the second external terminal side of the second circuit, and
the control unit controls the voltage adjustment circuit so that the input voltage in the estimation process is lower than the input voltage in the power transfer process.

14. The power conversion device according to claim 2, wherein
the control unit, in the estimation process, sets the fundamental wave component as a modulated wave, and sets a switching frequency in the switching control to a frequency higher than a resonant frequency of a resonant circuit including the resonant capacitor by PWM processing using the modulated wave and a carrier signal.

15. The power conversion device according to claim 14, wherein
the carrier signal is a triangular wave signal, and
the control unit, in the estimation process, sets a timing when the carrier signal becomes the maximum value or when the carrier signal becomes the minimum value as a detection timing of the estimation current.

16. A program applied to a power conversion device, the power conversion device comprising:
a first circuit, which is a bridge circuit connected to a first external terminal,
a second circuit, which is a bridge circuit connected to a second external terminal,
an inductance element connecting a first AC terminal of the first circuit and a second AC terminal of the second circuit,
a resonant capacitor connected to the inductance element, and
a control unit, wherein
the control unit is required to perform:
a power transfer process to transfer power between the first external terminal and the second external terminal via the inductance element by switching control of at least one of the first circuit and the second circuit, and
an estimation process to estimate an inductance of the inductance element by outputting a test voltage to the inductance element, wherein
a frequency of a fundamental wave component of the test voltage is set to a frequency lower than a frequency of a fundamental wave component of a voltage output to the inductance element in the power transfer process.
